(19) United States
(12) Patent Application Publication
(10) Pub. No.: US 2026/0190284 A1
(43) Pub. Date: Jul. 2, 2026

(54) APPARATUS, SYSTEMS, AND METHODS FOR COOLING ELECTRONIC DEVICES IN A CHASSIS

(71) Applicant: Intel Corporation, Santa Clara, CA (US)

(72) Inventors: Siva Prasad Jangili Ganga, Bengaluru (IN); Yogesh Ramakrishna Kuthkanahalli, Bengaluru (IN); Murali Macherla, Bangalore (IN); Ajmeerkaja Ayubkhan, Bangalore (IN); Soundararajan Narayanasamy, Hyderabad (IN)

(73) Assignee: Intel Corporation, Santa Clara, CA (US)

(21) Appl. No.: 19/331,616

(22) Filed: Sep. 17, 2025

(51) Int. Cl. H05K 7/20

(52) U.S. Cl. CPC H05K 7/20254; H05K 7/20154; H05K 7/20263; H05K 7/20772

(57) ABSTRACT

Apparatus, systems, and methods to provide cooling of electronic components in a chassis are disclosed. An example cold plate includes a housing having an inlet, an outlet, and a cavity; and a plate including a plurality of fins extending from the plate, the fins in the cavity, the plate integral with a surface of the housing.

### BACKGROUND

An electronic component such as a server generates heat during operation of the electronic component. In some instances, a liquid can be used to indirectly cool the electronic component via a cold plate that is thermally coupled to the electronic component and through which the liquid flows.

### BRIEF DESCRIPTION OF THE DRAWINGS

FIG. 1 is a cutaway view of an example chassis including an example printed circuit board, an example cold plate, and an example heat exchanger in accordance with teachings of this disclosure.

FIG. 2 illustrates an example cold plate in accordance with teachings of this disclosure.

FIG. 3 is a cross-sectional view of the example cold plate of FIG. 2 taken along the A-A line of FIG. 2.

FIG. 4 illustrates a fin assembly of the example cold plate of FIG. 2.

FIG. 5 illustrates a housing of the example cold plate of FIG. 2.

FIG. 6 illustrates the fin assembly of FIG. 4 and the housing of FIG. 5 prior to being integrally joined to form the example cold plate of FIG. 2.

FIG. 7 illustrates an example compute node in accordance with teachings of this disclosure.

FIG. 8 is a partial, cutaway view of the example chassis of FIG. 1, showing a heat exchanger carried by the chassis.

FIG. 9 is another partial, cutaway view of the example chassis of FIG. 1, showing fans carried by the chassis.

FIG. 10 is a top, cutaway view of the example chassis including schematic representations of example airflow paths through the chassis of FIG. 1.

FIG. 11 is a flowchart of an example method of manufacturing the example cold plate of FIG. 2 via an integral joining process in accordance with teachings of this disclosure.

FIG. 12 is a flowchart of an example method of assembling a cooling system for a compute node in the example chassis of FIG. 1 in accordance with teachings of this disclosure.

In general, the same reference numbers will be used throughout the drawing(s) and accompanying written description to refer to the same or like parts. The figures are not necessarily to scale.

### DETAILED DESCRIPTION

An electronic component such as a server may be located in an environment that is not regularly manned by a human operator due to ambient conditions. For example, the electronic component can be stored in a rack in an environment where the temperature may reach 65° C. (149° F.). During operation, the electronic component generates heat. An electronic component can has an associated thermal design power that may be measured in watts. The thermal design power represents a maximum amount of heat generated by the electronic component and corresponds to the amount of heat that should be dissipated via cooling to prevent overheating of the electronic component.

A liquid (e.g., a coolant) can be used to facilitate cooling of the electronic component (e.g., to supplement cooling provided by to transfer of the heat to ambient air). For instance, a cold plate can be thermally coupled to the electronic component to absorb heat generated by the electronic component via transfer of the heat to a liquid flowing through the cold plate. The heated liquid exits the cold plate via an outlet. Gaskets or other sealing devices can be used to form a seal between portions of the cold plate. Because the high temperature environments are often regularly unmanned, the electronic component thermally coupled to the cold plate and/or electronic component(s) proximate to the cold plate can be damaged by the leaked liquid before the leakage is detected. Therefore, leakage due to gasket failure or the like is to be avoided.

Electronic components such as a central processing unit, a graphics processing unit, a memory device, a network device, etc. may be coupled to a printed circuit board that is placed in a chassis. The printed circuit board and electronic components coupled thereto can be included in a compute node. In some instances, the chassis may carry two or more compute nodes (e.g., two or more printed circuit boards and corresponding electronic components). Thus, in some instances, a chassis is densely packed with heat generating components. The chassis can be stored on a rack that carries one or more other chassis and is located in, for example, a data center.

Disclosed herein are example apparatus, systems, and methods that cool electronic components in a chassis and, in particular, cool of electronic devices in a chassis that supports multiple compute nodes. Examples disclosed herein provide for a cold plate having a one-piece design with respect to (a) a housing of the cold plate through which a liquid flows and (b) a portion of the cold plate that includes fins (referred to herein as a fin assembly) to facilitate heat transfer. In examples disclosed herein, the housing and the fin assembly are integrally joined together via welding techniques such as friction welding or other solid-state welding techniques. In other examples, the housing and the fin assembly are integrally formed (e.g., via machining). Regardless of whether the housing and the fin assembly are internally joined or integrally formed, the housing and the fin assembly are an integral structure.

As used herein, stating that any part is “integrally joined” with another part is defined to mean that the two parts are permanently bonded, forged, fused, or otherwise merged via, for example, a joining process using heat, into a one-piece component. As used herein, stating that a part is “integrally formed” is defined to mean manufactured as a one-piece component. As used herein, stating that a part is in “contact” with another part is defined to mean that there is no intermediate part between the two parts. As used herein, stating that a part is “coupled” to another part may include intermediate members between the elements referenced by the connection reference and/or relative movement between those elements unless otherwise indicated.

As a result of the integral (e.g., one-piece) structure of the cold plates disclosed herein, disclosed example cold plates do not include gaskets or sealing devices between the housing and the fin assembly. Thus, examples disclosed herein do not include sealing devices that can fail when exposed to high ambient temperatures. Accordingly, example cold plates disclosed herein prevent leakage events at the cold plate that can damage the electronic component(s).

Also disclosed herein are example chassis that provide self-contained cooling environments for electronic components in the chassis. An example chassis disclosed herein includes a heat exchanger (e.g., a radiator) that is fluidly coupled to a cold plate. After liquid flows through the cold plate and absorbs heat generated by the electronic component to which the cold plate is thermally coupled, the liquid is received at the heat exchanger. Air flowing through the heat exchanger absorbs heat from the liquid exiting the outlet of the cold plate. The (cooled) liquid is returned to the inlet of the cold plate. Thus, examples disclosed herein provide for heat exchange and coolant circulation within the chassis. Therefore, examples disclosed herein eliminate the need for a separate heat exchanger (e.g., eliminate a cooling distribution unit) outside of the chassis to provide coolant for the cold plate.

In examples disclosed herein, one or more fans can be carried by the chassis to draw air into the chassis to cool the electronic components therein. In some examples, one or more of the fans are proximate to the heat exchanger to facilitate dissipation of the heat absorbed by the air flowing through the heat exchanger. In some examples, one or more heat exchanger(s) and one or more fan(s) are associated with the compute node(s) carried by the chassis. Thus, examples disclosed herein provide for self-contained cooling systems for compute nodes in a chassis using cold plates, heat exchangers, and fans carried by the chassis. Further, example cold plates, heat exchangers, and fans disclosed herein can be used with existing chassis, as these cooling devices can be placed in or coupled to the chassis without modifying or substantially modifying the chassis.

Also disclosed herein are example printed circuit board (PCB) arrangements that reduce pre-heating of air flowing through the chassis and, thus, increase efficiency of air-based cooling in the chassis. In examples disclosed herein, electronic components can be coupled to the PCB so that when the PCB is placed in the chassis, the electronic components that generate higher amounts of heat are in closer proximity to the fan(s) than the components that generate lower amounts of heat. The fan(s) of the chassis can facilitate air circulation within the chassis by drawing ambient air into inlets defined in the chassis and directing the ambient air to flow through the chassis toward the fans. By placing the electronic components that generate lower amounts of heat near the inlets through which the air enters the chassis, the temperature of the air flowing through a remainder of the chassis is lower than if the air entering the chassis was initially exposed to the higher heat-generating electronic components. Thus, examples disclosed herein reduce (e.g., prevent or substantially prevent) pre-heating of the air flowing into the chassis. The fan(s) of the chassis facilitate removal of the heated air from the chassis to cool the electronic components of the compute node. Also, the fan(s) can remove heated air generated at the heat exchanger associated with the compute node in the chassis. Thus, examples disclosed herein provide for independent cooling systems contained within a chassis that can withstand environments with high ambient temperatures (e.g., 65° C.) without exhibiting coolant leakage.

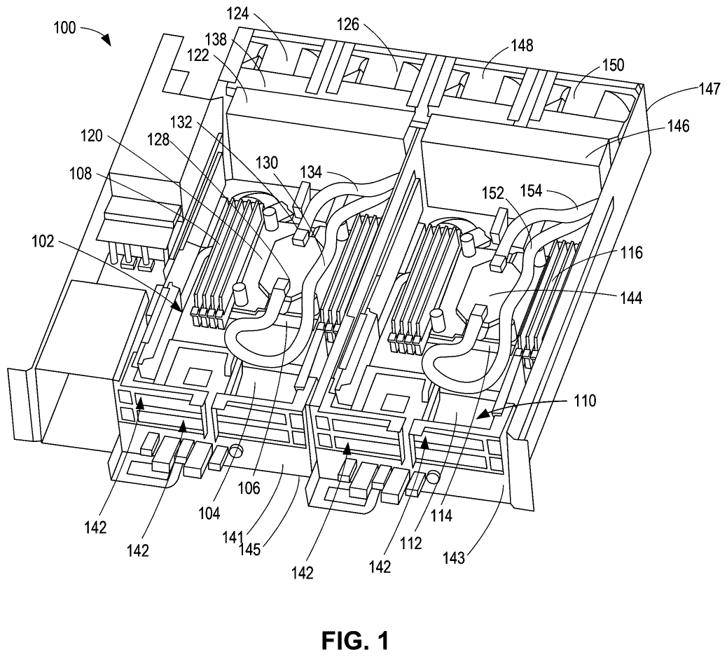

FIG. 1 is a cutaway view of an example chassis 100 in accordance with teachings of this disclosure. The example chassis 100 of FIG. 1 carries a first compute node 102 including a first printed circuit board 104 and electronic components coupled to the first printed circuit board 104, such as an integrated circuit (IC) in a package 106. The first printed circuit board 104 can carry other electronic components, such as memory devices 108 (Dual In-line Memory Module(s) (DIMM(s)); Peripheral Component Interconnect Express (PCIE) connectors; power connectors; etc. The first printed circuit board 104 can carry additional or fewer electronic components and/or different types of electronic components than shown in FIG. 1. Also, an arrangement of the electronic components on the first printed circuit board 104 can differ from the example of FIG. 1.

The example chassis 100 of FIG. 1 also carries a second compute node 110 including a second printed circuit board 112 and electronic components coupled to thereto, such as memory devices 116 and an integrated circuit package 114 including an IC. Thus, the example chassis 100 supports multiple compute nodes. In some examples, the chassis 100 has a 2U form factor. However, the chassis 100 can have other form factors, can support additional or fewer compute nodes, etc.

The example chassis 100 of FIG. 1 carries a first cooling system for the first compute node 102 and a second cooling system for the second compute node 110. The first cooling system of FIG. 1 includes a first cold plate 120, a first radiator 122 (i.e., a heat exchanger), a first fan 124, and a second fan 126. The first cooling system can include additional or fewer cold plates, radiators, and/or fans. In the example of FIG. 1, the cold plate 120 is coupled to the IC package 106 of the first printed circuit board 104 to facilitate transfer of heat from the IC package 106 to liquid (e.g., a coolant) flowing through the cold plate 120. The cold plate 120 can be coupled to the IC package 106 via fastener(s). However, the cold plate 120 can be coupled to other electronic components of the first printed circuit board 104. In some examples, two or more cold plates are used to cool electronic components of the first compute node 102.

In the example of FIG. 1, an inlet 128 of the first cold plate 120 is fluidly coupled to the first radiator 122 via first tubing 130 (e.g., a hose, such as an insulated hose or a thermal shield hose). Also, an outlet 132 of the cold plate 120 is fluidly coupled to the first radiator 122 via second tubing 134 (e.g., a hose). The first and second tubing 130, 134 define flow paths for liquid (e.g., a coolant) between the first radiator 122 and the first cold plate 120. The first radiator 122 includes a fluid source or reservoir (not shown) that stores the liquid (e.g., coolant) for circulation to the cold plate 120. In some examples, the liquid reservoir is separately located in the chassis 100. The liquid is delivered to the inlet 128 of the cold plate 120 via the first tubing 130. Heat generated by the IC package 106 is transferred to the cold plate 120 and then to the liquid flowing through the cold plate 120. The heated liquid exits the outlet 132 of the first cold plate 120, where it is carried by the second tubing 134 to the first radiator 122. At the first radiator 122, heat from the liquid is transferred to air flowing through the first radiator 124. The first radiator 122 can include fins to facilitate the heat transfer. The (cooled) liquid is recirculated to the first cold plate 120 via the first tubing 130.

The first and second fans 124, 126 facilitate circulation of air in the chassis 100 and removal of heated air from the chassis 100. In the example of FIG. 1, each of the first and second fans 124, 126 has a first side that faces the first radiator 122 and a second side that faces an exterior of the chassis 100. The first and second fans 124, 126 can be supported by a tray 138 that is carried by the chassis 100, where the tray 138 has openings to expose the first and second sides of each fan 124, 126. The first and second fans 124, 126 facilitate cooling of the electronic components (e.g., the IC package 106, the memory devices 108) of the first printed circuit board 104 by drawing cool air into the chassis 100 and promoting circulation of the air within the chassis 100.

In the example of FIG. 1, the chassis 100 includes at least one inlet 142 associated with a portion of the chassis 100 that houses the first compute node 102 and at least one inlet 142 associated with a portion of the chassis that houses the second compute node 110. As shown in FIG. 1, the chassis 100 includes inlets 142 that extend through a first sidewall 141 and inlets 142 that extend through a second sidewall 143, where the sidewalls 141, 143 are at the first side 145 of the chassis 100. In some examples, the first sidewall 141 and the second sidewall 143 are one sidewall that extends between portions of the chassis 100 including the compute nodes 102, 110. The example chassis 100 can have additional or fewer inlets 142 than show in FIG. 1. Also, the inlets 142 can have different sizes, shapes, and/or locations than shown in FIG. 1.

The first and second fans 124, 126 are located at a second side 147 of the chassis 100 opposite the first side 145 that includes the inlets 142. The first and second fans 124, 126 draw air into the chassis 100 via the inlets 142. Because the first and second fans 124, 126 are distal to the inlets 142 associated with the portion of the chassis 100 that houses the first compute node 102, air drawn into the chassis 100 flows over the first compute node 102, through the first radiator 122, and toward the first and second fans 124, 126. The first and second fans 124, 126 facilitate removal heated air from the chassis 100 to the ambient environment after the air absorbs heat generated by the electronic components of the first compute node 102. Also, as shown in FIG. 1, the air flows through the first radiator 122 prior to exiting the chassis 100 via the first and second fans 124, 126. The first and second fans 124, 126 cool the first radiator 122 by directing the heated air flowing through the first radiator 122 to exit the chassis 100.

Thus, the example first cooling system of FIG. 1 facilitates cooling of the first compute node 102 in the chassis 100 via liquid cooling through the cold plate 120 and air cooling via the fans 124, 126. Further, because the first radiator 122 and associated coolant reservoir are carried by the chassis 100, the first cooling system is a self-contained system in the chassis 100. The first cooling system of FIG. 1 does not include external heat exchangers (e.g., external refrigerant devices, external cooling distribution units) that would operate outside the chassis 100 to provide for liquid-to-air heat exchange and return of the cooled liquid to the chassis 100.

Similarly, the second cooling system for the second compute note 110 in the chassis 100 includes a second cold plate 144, a second radiator 146 (i.e., a heat exchanger), a third fan 148, and a fourth fan 150. The second cooling system can include additional or fewer cold plates, radiators, and/or fans. In the example of FIG. 1, the second cold plate 144 is thermally coupled to the IC package 114 of the second printed circuit board 112; however, the second cold plate 144 can be coupled to other electronic components of the second printed circuit board 112. The second cold plate 144 is fluidly coupled to the second radiator 146 via third tubing 152 that delivers a liquid from a reservoir associated with the second radiator 146 to an inlet of the second cold plate 144. Fourth tubing 154 carries heated liquid away from the second cold plate 144 after the liquid is exposed to heat generated by the electronic component to which the second cold plate 144 is thermally coupled. At the second radiator 146, heat is removed from the liquid before the liquid is re-circulated to the second cold plate 144.

The third and fourth fans 148, 150 can be carried by the tray 138 that carries the first and second fans 124, 126 or a separate tray. The third and fourth fans 148, 150 draw cool air into the chassis 100 via the inlets 142 (e.g., the inlets 142 associated with the portion of the chassis 100 including the second compute node 110, such as the inlets defined in the second sidewall 145). The air flows over and cools the electronic components of the second compute node 110. The third and fourth fans 148, 150 direct the air to flow through the second radiator 146 and to exit the chassis 100 into the ambient environment.

Thus, the example chassis 100 of FIG. 1 carries self-contained cooling systems to cool the first and second compute nodes 102, 110 in the chassis 100. The first cooling system (e.g., the first cold plate 120, the first radiator 122, the first and second fans 124, 126) and the second cooling system (the second cold plate 144, the second radiator 146, the third and fourth fans 148, 150) dissipate heat generated by the electronic components of the corresponding first compute node 102 and the second compute node 110. As a result, an overall temperature in the interior of the chassis 100 lowered. In some examples, the cooling system associated with a respective compute node 102, 110 can dissipate, for example, 350 W of heat generated by an electronic component (e.g., a system-on-chip) of a respective compute node 102, 110 at an ambient temperature of 65° C. Thus, the example cooling systems disclosed herein enable electronic components having increased thermal design power to be carried by the chassis 100 and stored in high ambient temperatures. Also, as disclosed herein, the first and second cold plates 120, 144 have a unitary construction that reduces (e.g., prevents) leakage of coolant from the cold plates 120, 144 into the chassis 100.

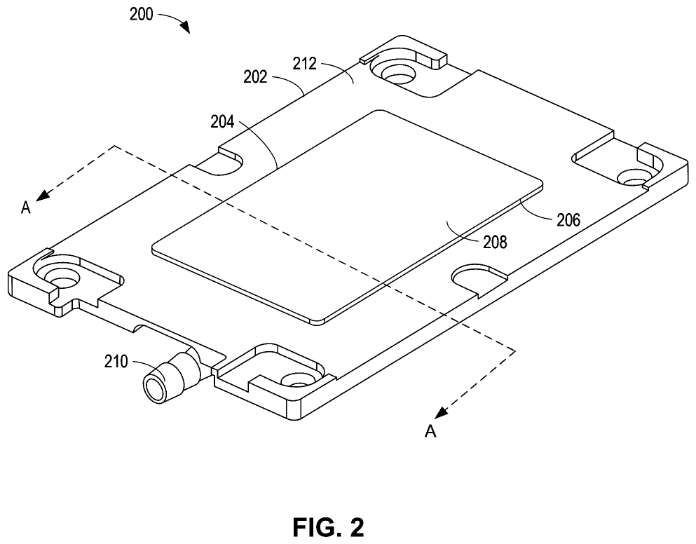

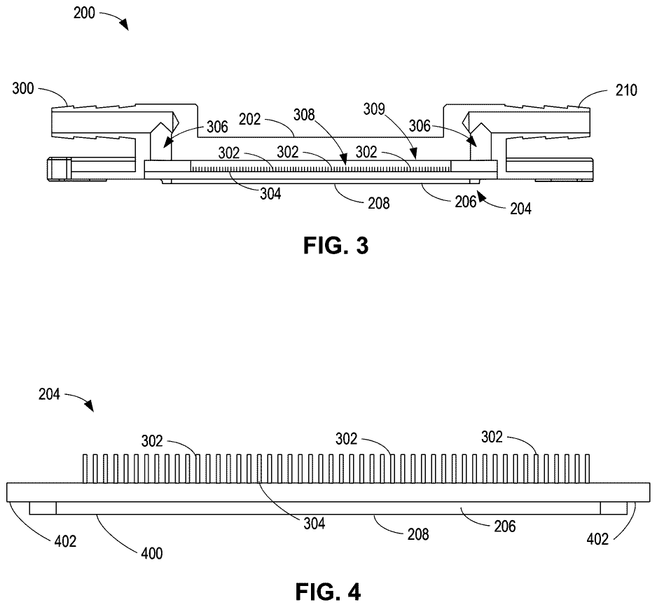

FIG. 2 illustrates an example cold plate 200, which can correspond to the first cold plate 120 and/or the second cold plate 144 of FIG. 1. The example cold plate 200 of FIG. 2 includes a housing 202 and a fin assembly 204. The housing 202 and the fin assembly 204 can be made of a metal material such as copper (e.g., CU-1100). The fin assembly 204 includes a plate 206 having a first surface 208 and an opposing surface (FIG. 3) that supports fins (FIG. 3). The fins (FIG. 3) extend into an interior of the housing 202.

The housing 202 of the example cold plate 200 defines an inlet (FIG. 3; e.g., the inlet 128 of FIG. 1) and an outlet 210 (e.g., the outlet 130 of FIG. 1) through which a liquid (e.g., a coolant) flows. When the cold plate 200 is thermally coupled to an electronic component (e.g., the IC package 106, 114 of FIG. 1), heat generated by the electronic component is transferred to the cold plate 200 (e.g., absorbed by the metal material of the cold plate 200). The heat absorbed by the cold plate 200 is transferred to the liquid flowing through the cold plate 200. As disclosed in connection with FIG. 1, the heated liquid exits the outlet 210 of the cold plate 200 and flows to a heat exchanger (e.g., the first or second radiator 122, 146) for cooling via transfer of heat to air flowing through the heat exchanger.

In the example of FIG. 2, the fin assembly 204 is integral with the housing 202. Put another way, the cold plate 200 is a unitary structure. For example, a portion of the plate 206 of the fin assembly 204 can be integrally joined to a first surface 212 of the housing 202 via a joining process that causes the fin assembly 204 to permanently bonded with the housing 202. For example, during a friction welding process, the portion of the plate 206 can be moved relative to the first surface 212 of the housing 202 such that the portion of the plate 206 forges with the first surface 212 due to frictional heat generated from the motion and without additional materials or fillers between the components. In other examples, the housing 202 and the fin assembly 204 are manufactured as a one-piece component via machining.

Thus, the example cold plate 200 of FIG. 2 is an integral (e.g., one-piece, unitary) structure. The example cold plate 200 does not use, for instance, fasteners, adhesives, etc. to couple the fin assembly 204 to the housing 202. Further, the example cold plate 200 of FIG. 2 does not include gaskets or other intermittent parts between the housing 202 and the fin assembly 204 to seal the cold plate 200 (e.g., to seal a chamber (FIG. 3) through which coolant flows in the cold plate 200). As such, coolant leakage events at the cold plate 200 of FIG. 2 are reduced (e.g., prevented).

FIG. 3 is a cross-sectional view of the example cold plate 200 of FIG. 2 taken along the A-A line of FIG. 2, wherein the orientation of the cold plate 200 in FIG. 3 is rotated relative to FIG. 2 such that the first surface 208 of the plate 206 of the fin assembly 204 is at the bottom of the cold plate 200. As shown in FIG. 3, the housing 202 includes an inlet 300 and the outlet 210. Also, the fin assembly includes fins 302 extending from a second surface 304 of the plate 206.

A flow path 306 extends from the inlet 300 into a chamber 308. In the example of FIG. 3, the chamber 308 is formed by a portion of the plate 206 of the fin assembly 204 (e.g., a portion of the second surface 304 of the plate 206) and a cavity 309 of the housing 202. Thus, as the liquid flows through the chamber 308, the liquid is exposed to the fins 302. The fins 302 facilitate transfer of the heat from the metal material of the cold plate 200 to the liquid flowing through the chamber 308. The heated liquid flows out of the chamber 308 and continues along the flow path 306, exiting the cold plate 200 via the outlet 210 of the cold plate 200.

FIG. 4 illustrates the example fin assembly 204 of the cold plate of FIG. 2. As disclosed in connection with FIGS. 2 and 3, the fin assembly 204 includes the plate 206 and the fins 302 extending from the surface 304 of the plate 206. The example plate 206 includes a first portion 400 and a second portion 402 that extends beyond a length of the first portion 400 (e.g., the second portion 402 overhangs the first portion 400 of the plate 206 in the orientation of the plate 206 shown in FIG. 4). In examples in which the cold plate 200 is formed by integrally joining the fin assembly 204 and the housing 202 (e.g., via welding), the additional length of the second portion 402 facilitates the fusing of the plate 206 to the housing 202 during the joining process. In some examples, a metal material defining the plate 206 is machined or molded to define the first and second plate portions 400, 402 (i.e., the plate 206 is integrally formed). In some examples, the first portion 400 and the second portion 402 of the plate 206 separately formed and integrally joined (e.g., welded) to form the plate 206. The first portion 400, the second portion 402, and/or, more generally, the plate 206 can have a different size and/or shape than shown in FIG. 4.

The fins 302 of the example fin assembly 204 can be manufactured using a skiving process. For example, the metal material of the plate 206 can be cut to define the fins 302 therein. In some examples, the first portion 400, the second portion 402, and the fins 302 are integrally formed from a single piece of material (e.g., copper). In some examples, the fins 302 are defined in a metal material that defines the second portion 402 and that is integrally joined to the first portion 400 to define the plate 206. In some examples, each fin 302 has a thickness of 0.3 mm, a height of 2.0 mm. A width of a spacing between each fin 302 can be, for example, 0.5 mm. However, the fins 302 can have different sizes and/or spacings. Also, the fins 302 can be formed at different angles than shown in FIG. 4.

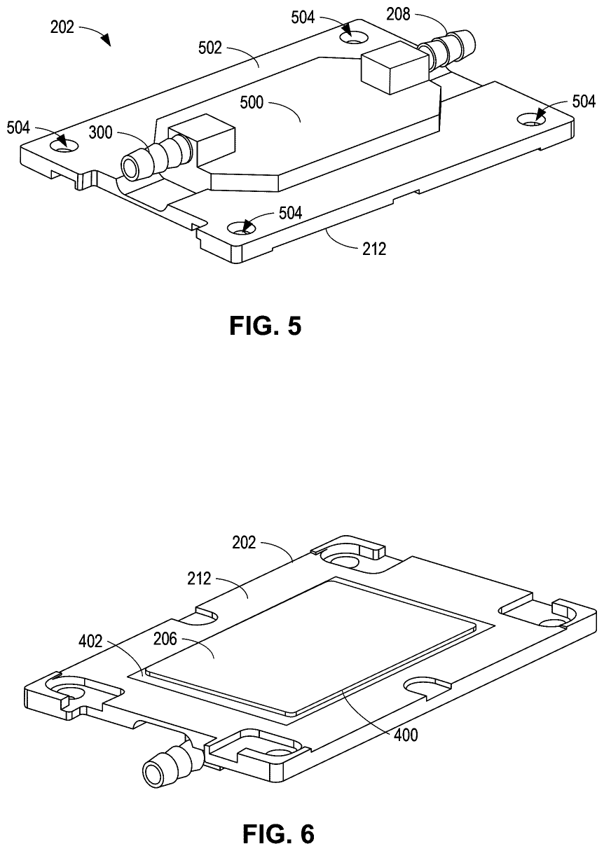

FIG. 5 illustrates the housing 202 of the example cold plate 200 of FIG. 2. As shown in FIG. 5, a portion 500 of the housing 202 protrudes relative to a second surface 502 of the housing 202 to define the cavity 309 (FIG. 3) of the housing 202. The second surface 502 of the housing 202 is opposite the first surface 212 of the housing 202. The cavity portion 500 defines a depth of the chamber 308 (FIG. 3) formed by the cavity 309 and the portion of the plate 206. As shown in FIG. 5, the inlet 300 and the outlet 210 extend from the cavity portion 500 to define the flow path 306 (FIG. 3) in the housing 202. The housing 202 can be manufactured (e.g., machined) such that the second surface 502, the cavity portion 500, the inlet 300, and the outlet 210 are formed from one piece (e.g., copper, CU-1100)). Openings 504 are formed (e.g., extruded) into the first and second surface 212, 502 of the housing 202 to enable the cold plate 200 to be mechanically coupled (e.g., via fasteners such as screws) to an electronic component, such as the IC package 106, 114 of FIG. 1. A size and/or location of the respective openings 504 can differ from the example shown in FIG. 5.

FIG. 6 illustrates the example cold plate 200 of FIG. 2 prior to the fin assembly 204 being integrally joined (e.g., welded to) the housing 202. The fin assembly 204 is placed on the housing 202 such that the fins 302 (FIG. 3) extend into the cavity 309 (FIG. 3) of the housing 202 and the second plate portion 402 of the plate 206 contacts the first surface 212 of the housing 202. In examples in which the fin assembly 204 and the housing 202 undergo an integral joining process such as friction welding, forces applied to the fin assembly 204 and resulting motion of the fin assembly 204 relative to the housing 202 create friction. The frictional forces generate heat sufficient to cause the first surface 212 of housing 202 and the second portion 402 of the fin assembly 204 in contact with the first surface 212 of the housing 202 to soften and create a bond. In this example, the first portion 400 of the plate 206 remains elevated or protrudes relative to the first surface 212 of the housing 202 after the integral joining process. However, in other examples, the plate 206 does not protrude or does not substantially protrude relative to the first surface 212 of the housing 202.

Although examples disclosed herein are primarily discussed with respect to friction welding to integrally join the fin assembly 204 and the housing 202, other integral joining processes, such as fusion welding (e.g., based on melting components), could be used to form the cold plate of FIGS. 2-6. Also, as disclosed herein, in other examples, the cold plate 200 of FIGS. 2-6 can be integrally formed as one piece via machining.

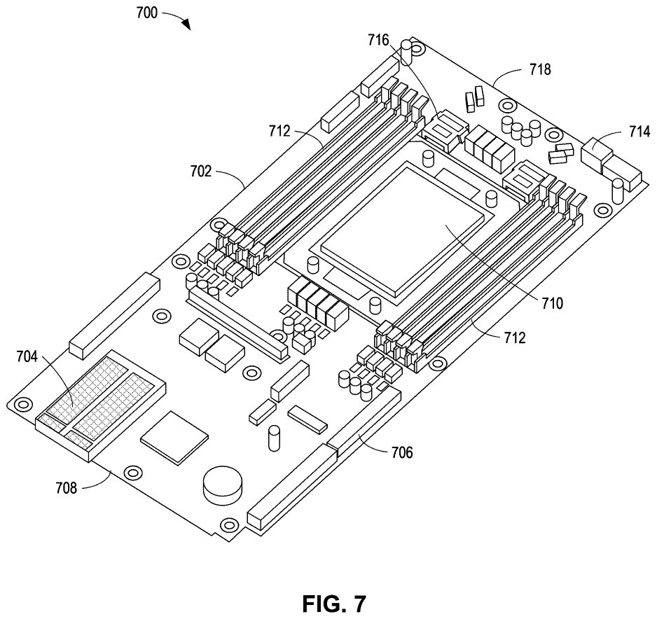

FIG. 7 illustrates an example compute node 700, which can correspond to the first compute node 102 or the second compute node 110 of FIG. 1. In the example of FIG. 7, the electronic components are selectively arranged on a printed circuit board (PCB) 702 (e.g., the PCB 104, 112 of FIG. 1) to increase efficiency of cooling when the compute node 700 is in the chassis 100 of FIG. 1.

In the example of FIG. 7, electronic components that generate lower amounts of heat are coupled to the PCB 702 proximate to a first side 708 of the PCB 702. Electronic components that generate higher amounts of heat are coupled to the PCB 702 proximate to a second side 718 of the PCB 702, where the second side 718 is opposite the first side 708 of the PCB 702. For example, electronic components such as a quad small form factor pluggable (QSFP) cage 704 and PCIE connector(s) 706 are proximate to the first side 708 of the PCB 702. Electronic components such as an integrated circuit (IC) package 710 (e.g., the IC package 106, 114 of FIG. 1); memory devices 712 such as DIMMS (e.g., the memory devices 108, 116 of FIG. 1); power connector(s) 714; and Ethernet network processing card(s) 716 (e.g., NPC(s)) are distal to the first side 708 of the PCB 702 (e.g., farther from the first side 708 than the QSFP cage 704 and PCIE connectors 706) and more proximate to the second side 718 of the PCB 702. The example compute node 700 can include additional or fewer electronic components and/or different types of electronic components. Also, locations(s) of the electronic component(s) on the PCB 702 can differ from the example shown in FIG. 7.

Referring to FIG. 1, when the compute node 700 of FIG. 7 (which can correspond to the first compute node 102 or the second compute node 110) is placed in the chassis 100, the first side 708 of the PCB 702 is proximate to the first side 145 of the chassis 100, or the portion of the chassis 100 including the inlets 142 through which air enters the chassis 100. The second side 718 of the PCB 702 is proximate to the second side 147 of the chassis 100 of FIG. 1 (e.g., the portion of the chassis 100 including the corresponding radiators 122, 146 and corresponding fans 124, 126, 148, 150 of the first or second cooling systems). Thus, the lower heat generating components such as the QSFP cage 704 and PCIE connector(s) 706 are closer to the inlets 142 of the chassis 100. Because electronic components such as the QSFP cage 704 and PCIE connector(s) 706 generate lower amounts of heat than, for example, the IC package 710 and the memory devices 712, air following into the inlets 142 and past the electronic components 704, 706 absorbs less heat than if the higher heat-generating component(s) 710, 712, 714, 716 were located closer to the inlets 142. Put another way, pre-heating of air flowing through the chassis 100 before the air reaches the higher heat-generating component(s) 710, 712, 714, 716 is reduced (e.g., minimized).

Thus, when the air reaches the higher heat-generating component(s) 710, 712, 714, 716, the air can cool the higher heat-generating component(s) 710, 712, 714, 716 more efficiently than if the air was already pre-heated.

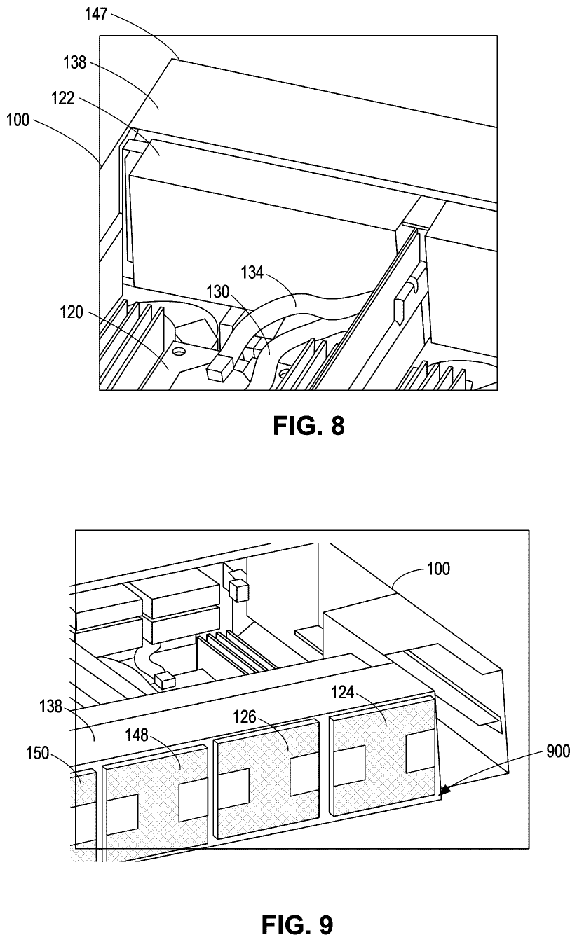

FIG. 8 is a cutaway view of the example chassis 100 of FIG. 1, showing a portion of the chassis 100 including the example first radiator 122 of FIG. 1. Although FIG. 8 is discussed in connection with the first radiator 122 associated with the first compute node 102 of FIG. 1, the discussion of FIG. 8 similarly applies to the example second radiator 146 associated with the second compute node 110 of FIG. 1. As shown in FIG. 8, the first radiator 122 is located proximate to an electronic component (e.g., a higher heat-generating component such as the IC package 106 of FIG. 1) that is coupled with the first cold plate 120. Thus, a length of the first and second tubing 130, 134 that extends from the first cold plate 120 can be reduced because of the proximity of the first cold plate 120 to the first radiator 122.

As also shown in FIG. 8, the first radiator 122 is proximate to fan tray 138 at the second side 147 of the chassis 100. Put another way, the first radiator 122 is distal to the inlets 142 (FIG. 1) defined in the first sidewall 143 (FIG. 1). Air flows through the first radiator 122 and then exits the chassis 100 via the first and second fans 124, 126 (FIG. 1). The location of the first radiator 122 proximate to the fans 124, 126 helps to reduce the temperature of an interior of the chassis 100, as the heated air generated at the first radiator 122 does not circulate or substantially circulate within the chassis 100 (as compared to if the first radiator 122 were located proximate to the inlets 142). The chassis 100 can include additional radiators than shown in FIG. 8.

FIG. 9 is a cutaway view of the example chassis 100 of FIG. 1, showing a portion of the chassis 100 including the tray 138 that carries the fans 124, 126, 148, 150. In the example of FIG. 9, the tray 138 extends between the portions of the chassis 100 that house the first compute node 102 and the second compute node 110. However, in other examples, the fans 124, 126, 148, 150 can be carried by two or more trays. As shown in FIG. 9, the tray 138 includes an opening 900 such that a first side of each of the fans 124, 126, 148, 150 is exposed to an exterior of the chassis 100, thereby enabling the fans 124, 126, 148, 150 to drive air to exit the chassis 100. Also, an opposing side of the tray 138 is open to enable the fans 124, 126, 148, 150 to draw air into the chassis 100 (e.g., via the inlets 142 of FIG. 1). The chassis 100 can include additional or fewer fans than shown in FIG. 9. Aso, a size and/or shape of the tray 138 can differ from the example of FIG. 9.

The radiators 122, 146 and the fan tray 138 carrying the fans 124, 126, 148, 150 can be placed in an existing chassis to provide cooling system(s) for compute node(s) in the chassis. The radiators 122, 146 and the fans 124, 126, 148, 150 can be selected to have dimensions that fit within, for example, a single node chassis (e.g., a 2U single node chassis). In some examples, the number of radiators 122, 146 and/or the fans 124, 126, 148, 150 in the chassis is based on the number of compute nodes in the chassis, the heat thermal design power of the electronic components of the compute node(s), etc. In some examples, the radiator 122, 146 has a width of 162 mm, a height of 83 mm, and a depth of 86 mm and supports a liquid flow rate of 3 liters per minute. However, the radiators 122, 146 can have a different size and/or shape, and/or support different flow rates. In some examples, the fans have a width of 80 mm and a length of 80 mm and can operate at speeds of 4800 revolutions per minute. However, the fans 124, 126, 148, 150 can have different sizes and/or shapes, and/or can support different rotational speeds.

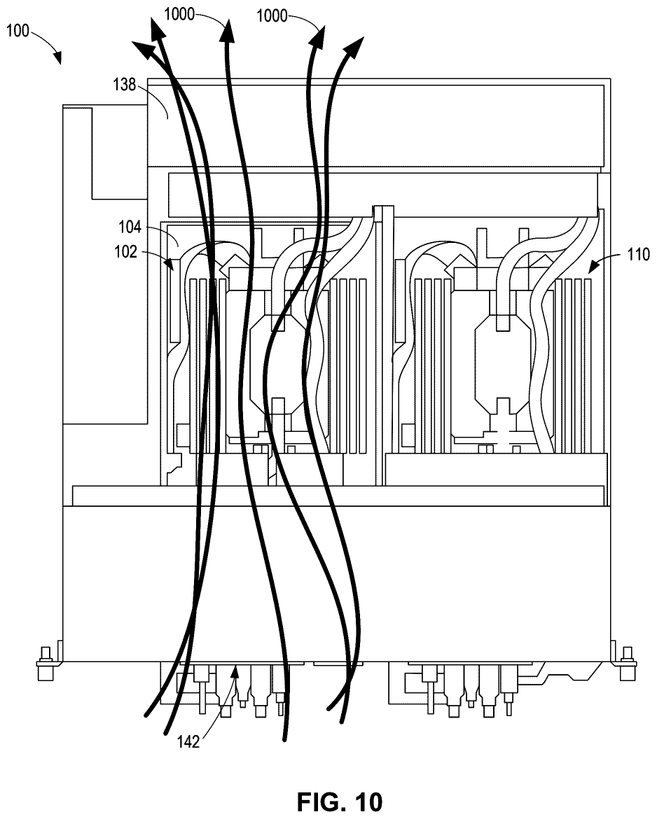

FIG. 10 is a top view of the example chassis 100 of FIG. 1 including schematic arrows 1000 representing air flow through a portion of the chassis 100 in which the first compute node 102 is located. Although FIG. 10 is discussed in connection with the first compute node 102, the discussion of FIG. 10 similarly applies to the example second compute node 110 in the chassis 100. As represented by the arrows 1000, during operation of the fans 124, 126 (FIG. 1) air is drawn into the chassis 100 through the inlets 142 associated with a portion of the chassis 100 that carries the first compute node 102. The air passes over the electronic components coupled to the printed circuit board 104 of the first compute node 102. As disclosed in connection with FIG. 7, the electronic components can be arranged on the printed circuit board 104 such that the lower heat-generating electronic components (e.g., the PCIE connectors 706 of FIG. 7) are proximate to the inlets 142 to reduce (e.g., minimize) pre-heating of the air as the air travels toward the higher heat-generating electronic components (e.g., the memory devices 108, 712 the IC package 106, 710 of FIGS. 1 and 7) and the first radiator 122. The air exits the chassis 100 via the fans 124, 126 (FIG. 1).

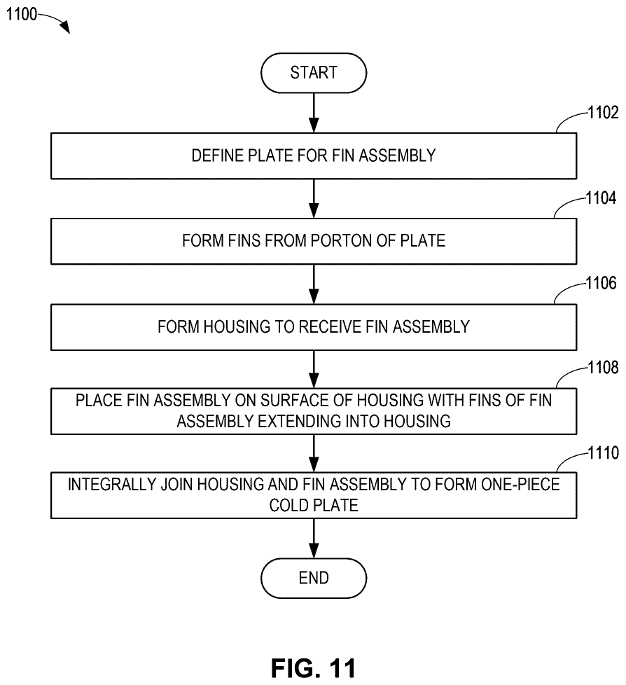

FIG. 11 is a flowchart of an example method 1100 of manufacturing a cold plate, such as the example cold plate 200 of FIGS. 2-6, via an integral joining process.

At block 1102, the example method 1100 includes defining the plate 206 for the fin assembly 204. For example, a metal material such as copper can be machined to define the first portion 400 and the second portion 402 of the plate 206, where the second plate portion 400 extends beyond a length of the first plate portion 400. In some examples, the first and second plate portions 400, 402 are integrally formed from one piece of metal to define the plate 206. In some examples, the first and second plate portions 400, 402 are separately formed and integrally joined (e.g., welded) to define the plate 206.

At block 1104, the example method 1100 includes forming the fins 302 from a portion of the plate 206. For example, a skiving process can be used to define the fins 302 from a material that defines the second portion 402 of the plate 206.

At block 1106, the example method 1100 includes forming the housing 202 to the receive the fin assembly 204. For example, a metal material such as copper can be machined or molded to form the inlet 300, the outlet 210, the flow path 306, the chamber portion 500, and the openings 504 of the of the housing 202.

At block 1108, the example method 1100 includes placing the fin assembly 204 on the housing 202 such that the second portion 402 of the plate 206 contacts the surface 212 of the housing 202 and the fins 302 extend into the chamber portion 500 of the housing 202.

At block 1110, the example method 1100 includes integrally joining the housing 202 and the fin assembly 204 to form a one-piece cold plate. For example, the housing 202 and the fin assembly 204 can be integrally joined via friction welding such that the second portion 402 of the fin assembly 204 permanently bonds with the first surface 212 of the housing 202.

While an example manner of manufacturing a cold plate is illustrated in FIG. 11, one or more of the elements, processes and/or devices illustrated in FIG. 11 may be combined, divided, re-arranged, omitted, eliminated, and/or implemented in any other way.

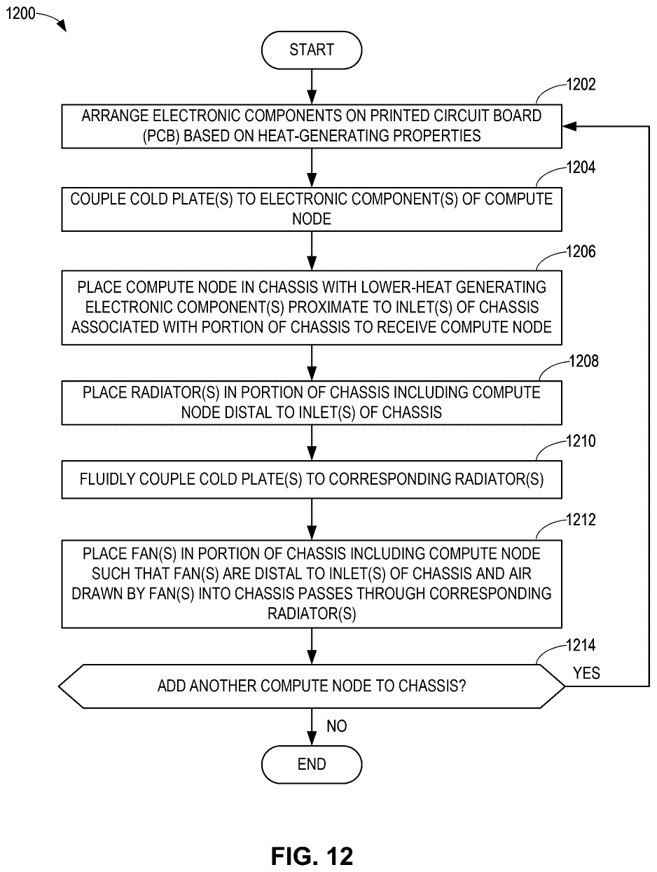

FIG. 12 is a flowchart of an example method 1200 of assembling a cooling system for a compute node in a chassis, such as the example chassis 100 of FIG. 1 including the compute nodes 102, 110, 700 of FIGS. 1 and 7.

At block 1202, the example method 1200 includes assembling electronic components on a printed circuit board 104, 112, 702 based on heat-generating properties of the electronic components. For example, lower heat-generating components such as the QSFP cage 704 and the PCIE connectors 706 can be coupled to the PCB 104, 112, 702 proximate to a first side 708 of the PCB 104, 112, 702. Higher heat-generating components such as the IC package 106, 710 and the memory devices 712 can be coupled to the PCB 104, 112, 702 proximate to a second side 718 of the PCB 104, 112, 702.

At block 1204, the example method 1200 includes thermally coupling the cold plate(s) 120, 144, 200 to one or more of the electronic components of the compute node 102, 110, 700, such as the IC package 106, 114, 710. For example, the cold plate(s) 120, 144, 200 can be coupled to the electronic component(s) via fasteners extending through the openings 504 of the cold plate(s) 120, 144, 200.

At block 1206, the example method 1200 includes placing the compute node 102, 110, 700 in the chassis 100 with the lower heat-generating electronic component(s) proximate to the inlets 142 of the chassis 100 that are associated with a portion of the chassis 100 that is to receive the compute node 102, 110, 700.

At block 1208, the example method 1200 includes placing radiator(s) 122, 146 in a portion of the chassis 100 that includes the compute node 102, 110, 700, where the radiator(s) 122, 146 are distal to the inlets 142 of the chassis 100.

At block 1210, the example method 1200 includes fluidly coupling the cold plate(s) 120, 144, 200 to the corresponding radiator(s) 122, 146. For example, the cold plate(s) 120, 144, 200 can be fluidly coupled to the corresponding radiator(s) 122, 146 via the tubing 130, 134, 152, 154.

At block 1212, the example method 1200 includes placing the fan(s) 124, 126, 148, 150 in the portion of the chassis 100 including the compute node 102, 110, 700 and distal to the inlets 142 (i.e., distal to the inlets 142 to which the lower heat-generating electronic component(s) of the compute node 102, 110, 700 are proximate). Also, the fan(s) 124, 126, 148, 150 can be placed in the chassis 100 such that air drawn into the chassis by the fan(s) 124, 126, 148, 150 passes through the corresponding radiator(s) 122, 146 to cool the radiator(s) 122, 146. The fan(s) 124, 126, 148, 150 can be placed in the chassis 100 such that a portion of the respective fan(s) 124, 126, 148, 150 faces an exterior of the chassis 100.

If, at block 1214, another compute node 102, 110, 700 is to be added to the chassis 100, then blocks 1202-1212 are repeated to provide for cooling of the compute node(s) 102, 110, 700 in the chassis 100.

While an example manner of assembling cooling system(s) for compute node(s) in a chassis is illustrated in FIG. 12, one or more of the elements, processes and/or devices illustrated in FIG. 12 may be combined, divided, re-arranged, omitted, eliminated, and/or implemented in any other way.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that provide cooling system(s) in a chassis that houses one or more compute nodes. Example cooling systems disclosed herein are self-contained within the chassis and include cold plate(s), radiator(s), and fan(s) that cool respective compute node(s) in the chassis. Example compute nodes can include electronic components arranged on a printed circuit board based on heat-generating properties of the electronic components, where electronic components that generate lower amounts of heat are exposed to air flowing through the chassis before electronic components that generate higher amounts of heat. As a result, examples disclosed herein reduce pre-heating of the air by the most heat intensive component(s) and, thus, provide for efficient cooling within the chassis. Examples disclosed herein also provide for cold plates having an integral (e.g., one-piece) construction, thereby eliminating components (e.g., between the cold plate housing and the fin assembly), such as gaskets or other seals that may fail under high temperatures. Accordingly, example cold plates disclosed herein reduce (e.g., prevent) leakage events due to failure of sealing devices. As such, examples disclosed herein provide self-contained and reliable cooling systems that can be used to cool electronic components in environments that may be not regularly manned by human operators.

Example apparatus, systems, and methods to provide cooling of electronic components in a chassis are disclosed. Further examples and combinations thereof include the following:

Example 1 includes a cold plate including a housing having an inlet, an outlet, and a cavity; and a plate including a plurality of fins extending from the plate, the fins in the cavity, the plate integral with a surface of the housing.

Example 2 includes any of the preceding clause(s) of Example 1, wherein the plate and the housing are a one-piece structure.

Example 3 includes any of the preceding clause(s) of any one or more of Examples 1-2, wherein the plate and the surface of the housing are integrally joined by a weld.

Example 4 includes any of the preceding clause(s) of any one or more of Examples 1-3, wherein a portion of the plate and the cavity of the housing define a chamber and wherein the inlet, the outlet, and the chamber define a flow path for a liquid through the cold plate.

Example 5 includes any of the preceding clause(s) of any one or more of Examples 1-4, wherein a portion of the plate protrudes relative to the surface of the housing.

Example 6 includes any of the preceding clause(s) of any one or more of Examples 1-5, wherein the inlet and the outlet extend from a portion of the housing defining the cavity.

Example 7 includes any of the preceding clause(s) of any one or more of Examples 1-6, wherein the housing and the plate include copper.

Example 8 includes an apparatus including a chassis having an inlet proximate to a first side of the chassis; a compute node in the chassis; a cold plate thermally coupled to an electronic component of the compute node, the cold plate including a housing, a plate, and fins extending from the plate into the housing, the housing integral with the plate; a heat exchanger in the chassis, the heat exchanger fluidly coupled to the cold plate; and a fan in the chassis, the fan proximate to a second side of the chassis, the second side of the chassis opposite the first side of the chassis, the fan to draw air into the chassis via the inlet, the air to flow through the heat exchanger prior to exiting the chassis.

Example 9 includes any of the preceding clause(s) of Example 8, wherein the heat exchanger is proximate to the second side of the chassis.

Example 10 includes any of the preceding clause(s) of any one or more of Examples 8-9, wherein the electronic component is proximate to a first side of a printed circuit board, the first side of the printed circuit board proximate to the fan in the chassis and a second side of the printed circuit board proximate to the inlet, the second side of the printed circuit board opposite the first side of the printed circuit board.

Example 11 includes any of the preceding clause(s) of any one or more of Examples 8-10, wherein the electronic component is a first electronic component and the compute node includes a second electronic component proximate to the second side of the printed circuit board, the first electronic component to generate a higher amount of heat than the second electronic component.

Example 12 includes any of the preceding clause(s) of any one or more of Examples 8-11, wherein the compute node includes a third electronic component proximate to the first side of the printed circuit board, the third electronic component to generate a higher amount of heat than the second electronic component.

Example 13 includes any of the preceding clause(s) of any one or more of Examples 8-12, wherein the cold plate includes an inlet and an outlet, the heat exchanger fluidly coupled to the inlet of the cold plate via first tubing and fluidly coupled to the outlet of the cold plate via second tubing.

Example 14 includes any of the preceding clause(s) of any one or more of Examples 8-13, wherein the compute node is a first compute node, the cold plate is a first cold plate, the heat exchanger is first heat exchanger, the fan is a first fan, and including a second cold plate thermally coupled to an electronic component of a second compute node in the chassis, wherein the second cold plate is a unitary structure; a second heat exchanger in the chassis and fluidly coupled to second cold plate; and a second fan, the first fan and the second fan carried by a tray in the chassis.

Example 15 includes a method including forming a plate; forming a plurality of fins extending from a surface of the plate; forming a housing including an inlet, an outlet, and a cavity; placing the plate on a surface of the housing, the fins extending into the cavity; and integrally joining a portion of the plate to the surface of the housing.

Example 16 includes any of the preceding clause(s) of Example 15, wherein forming the plurality of fins includes skiving a material of the plate to form the fins.

Example 17 includes any of the preceding clause(s) of any one or more of Examples 15-16, wherein the integrally joining includes welding the portion of the plate to the surface of the housing via friction welding.

Example 18 includes any of the preceding clause(s) of any one or more of Examples 15-17, wherein forming the housing includes machining the inlet, the outlet, and the cavity from one piece.

Example 19 includes any of the preceding clause(s) of any one or more of Examples 15-18, wherein forming the plate includes forming a first plate portion and a second plate portion extending beyond a length of the first plate portion.

Example 20 includes any of the preceding clause(s) of any one or more of Examples 15-19, wherein the integrally joining includes welding the second plate portion to the surface of the housing.

Example 21 includes a method including coupling a cold plate to an electronic component of a compute node, the cold plate being an integral structure, the compute node in a first portion of a chassis; placing a heat exchanger in the first portion of the chassis and distal to an inlet of the chassis; fluidly coupling the cold plate to the heat exchanger; and placing a fan in the first portion of the chassis and distal to the inlet, a portion of the fan to face an exterior of the chassis.

Example 22 includes any of the preceding clause(s) of Example 21, including coupling a first electronic component to a printed circuit board of the compute node proximate to a first side of the printed circuit board; coupling a second electronic component to the printed circuit board proximate to a second side of the printed circuit board, the second side opposite the first side, the first electronic component to generate a higher amount of heat than the second electronic component; and placing the printed circuit board in the first portion of the chassis with the second side of the printed circuit board proximate to the inlet of the chassis.

Example 23 includes any of the preceding clause(s) of any one or more of Examples 21-22, wherein the compute node is a first compute node, the inlet is a first inlet, the heat exchanger is a first heat exchanger, the fan is a first fan, and including placing a second compute node in a second portion of the chassis; placing a second heat exchanger in the second portion of the chassis distal to a second inlet of the chassis; and placing a second fan in the second portion of the chassis and distal to the second inlet, a portion of the second fan to face the exterior of the chassis.

Example 24 includes any of the preceding clause(s) of any one or more of Examples 21-23, wherein the cold plate is a first cold plate and including thermally coupling a second cold plate to an electronic component of the second compute node; and fluidly coupling the second cold plate to the second heat exchanger.

Example 25 includes any of the preceding clause(s) of any one or more of Examples 21-24, including welding a housing and a fin assembly to form the cold plate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. A cold plate comprising:
a housing having an inlet, an outlet, and a cavity; and
a plate including a plurality of fins extending from the plate, the fins in the cavity, the plate integral with a surface of the housing.

2. The cold plate of claim 1, wherein the plate and the housing are a one-piece structure.

3. The cold plate of claim 1, wherein the plate and the surface of the housing are integrally joined by a weld.

4. The cold plate of claim 1, wherein a portion of the plate and the cavity of the housing define a chamber and wherein the inlet, the outlet, and the chamber define a flow path for a liquid through the cold plate.

5. The cold plate of claim 1, wherein a portion of the plate protrudes relative to the surface of the housing.

6. The cold plate of claim 1, wherein the inlet and the outlet extend from a portion of the housing defining the cavity.

7. The cold plate of claim 1, wherein the housing and the plate include copper.

8. An apparatus comprising:
a chassis having an inlet proximate to a first side of the chassis;
a compute node in the chassis;
a cold plate thermally coupled to an electronic component of the compute node, the cold plate including a housing, a plate, and fins extending from the plate into the housing, the housing integral with the plate;
a heat exchanger in the chassis, the heat exchanger fluidly coupled to the cold plate; and
a fan in the chassis, the fan proximate to a second side of the chassis, the second side of the chassis opposite the first side of the chassis, the fan to draw air into the chassis via the inlet, the air to flow through the heat exchanger prior to exiting the chassis.

9. The apparatus of claim 8, wherein the heat exchanger is proximate to the second side of the chassis.

10. The apparatus of claim 8, wherein the electronic component is proximate to a first side of a printed circuit board, the first side of the printed circuit board proximate to the fan in the chassis and a second side of the printed circuit board proximate to the inlet, the second side of the printed circuit board opposite the first side of the printed circuit board.

11. The apparatus of claim 10, wherein the electronic component is a first electronic component and the compute node includes a second electronic component proximate to the second side of the printed circuit board, the first electronic component to generate a higher amount of heat than the second electronic component.

12. The apparatus of claim 11, wherein the compute node includes a third electronic component proximate to the first side of the printed circuit board, the third electronic component to generate a higher amount of heat than the second electronic component.

13. The apparatus of claim 8, wherein the cold plate includes an inlet and an outlet, the heat exchanger fluidly coupled to the inlet of the cold plate via first tubing and fluidly coupled to the outlet of the cold plate via second tubing.

14. The apparatus of claim 8, wherein the compute node is a first compute node, the cold plate is a first cold plate, the heat exchanger is first heat exchanger, the fan is a first fan, and including:
a second cold plate thermally coupled to an electronic component of a second compute node in the chassis, wherein the second cold plate is a unitary structure;
a second heat exchanger in the chassis and fluidly coupled to second cold plate;
and a second fan, the first fan and the second fan carried by a tray in the chassis.

15. A method comprising:
forming a plate;
forming a plurality of fins extending from a surface of the plate;
forming a housing including an inlet, an outlet, and a cavity;
placing the plate on a surface of the housing, the fins extending into the cavity; and
integrally joining a portion of the plate to the surface of the housing.

16. The method of claim 15, wherein forming the plurality of fins includes skiving a material of the plate to form the fins.

17. The method of claim 15, wherein the integrally joining includes welding the portion of the plate to the surface of the housing via friction welding.

18. The method of claim 15, wherein forming the housing includes machining the inlet, the outlet, and the cavity from one piece.

19. The method of claim 15, wherein forming the plate includes forming a first plate portion and a second plate portion extending beyond a length of the first plate portion.

20. The method of claim 19, wherein the integrally joining includes welding the second plate portion to the surface of the housing.

21-25. (canceled)
